(19) United States
(12) Patent Application Publication
(10) Pub. No.: US 2010/0323108 A1
(43) Pub. Date: Dec. 23, 2010

(54) DEPOSITION APPARATUS AND DEPOSITION METHOD

(75) Inventors: Kanji Yasui, Niigata (JP); Hiroshi Nishiyama, Niigata (JP); Yasunobu Inoue, Niigata (JP); Hitoshi Miura, Niigata (JP)

Correspondence Address: IPUSA, P.L.L.C, 1054 31ST STREET, N.W., Suite 400, Washington, DC, 20007, US

(73) Assignees: NATIONAL UNIVERSITY CORPORATION NAGAOKA UNIVERSITY OF TECHNOLOGY, NAGAOKA-SHI, NIIGATA (JP); TOKYO ELECTRON LIMITED, MINATO-KU, TOKYO (JP)

(21) Appl. No.: 12/864,904

(22) PCT Filed: Nov. 21, 2008
(86) PCT No.: PCT/JP2008/071253

§ 371 Date: Sep. 7, 2010

(30) Foreign Application Priority Data
Jan. 29, 2008 (JP) 2008-017413

(51) Int. Cl. C23C 16/448; C23C 16/00

(52) U.S. Cl. 427/255.28; 118/715

(57) ABSTRACT

A disclosed deposition apparatus includes a catalyst reaction apparatus including an introduction part that introduces a first source gas, a catalyst container that contains a catalyst that produces reactive gas from the first source gas introduced from the introduction part, and a reactive gas ejection part that ejects the reactive gas from the catalyst container; a reactive gas separator that allows the reactive gas ejected from the reactive gas ejection part to go therethrough; a substrate supporting part that supports a substrate; and a supplying part that supplies a second source gas that reacts with the reactive gas that passes through the reactive gas separator, thereby depositing a film on the substrate.

### TECHNICAL FIELD

The present invention relates to a film deposition apparatus that deposits a thin film of metal oxides such as zinc oxide, a thin film of metal nitrides such as gallium nitride and aluminum nitride, and a thin film of silicon nitride on a substrate.

### BACKGROUND ART

As a film deposition method that deposits thin films of metal oxides such as zinc oxide, metal nitrides such as gallium nitride and aluminum nitride, and silicon nitride on various substrates, a large number of methods have been proposed that include physical vapor deposition (PVD) methods such as a pulse laser deposition (PLD) method, a laser ablation method, and a sputtering method, and chemical vapor deposition (CVD) methods such as a metal organic chemical vapor deposition (MOCVD) method, and a plasma assisted chemical vapor deposition (plasma CVD) method (see Patent Documents 1 through 5, for example).

Patent Document 1: Japanese Patent Application Laid-Open Publication No. 2004-244716.

Patent Document 2: Japanese Patent Application Laid-Open Publication No. 2000-281495.

Patent Document 3: Japanese Patent Application Laid-Open Publication No. H6-128743.

Patent Document 4: Japanese Patent Application Laid-Open Publication No. 2004-327905.

Patent Document 5: Japanese Patent Application Laid-Open Publication No. 2004-103745.

### SUMMARY OF INVENTION

### Problems to be Solved by the Invention

In the above PVD, a laser beam, high energy particles, or the like are bombarded onto a target that has been prepared in advance, thereby causing particles of the target, which are generated from an upper surface of the target, to be deposited on the substrate. In the MOCVD, a metal organic compound and a hydrogen compound are exposed to the substrate that is heated at higher temperatures, thereby causing a film to be deposited on the substrate by making use of chemical deposition that takes place on the upper surface of the substrate. In the plasma CVD, a mixed gas of a source gas including a constituent element of a film to be deposited and a hydrogen compound are excited by high frequency electric power to generate plasma, thereby causing a film to be deposited on the substrate through recombination of radicals.

In addition, when depositing, for example, a GaN film, because an ammonia gas serving as a nitrogen source is persistent, it is necessary to supply the ammonia gas at a greater flow rate than that of a metal organic compound of gallium by a factor of 1000 or more, in a usual MOCVD, which demands an improvement from viewpoints of natural resources saving and a considerable expense required to treat unreacted toxic ammonia gas.

In view of the above, the present invention is aimed at providing a film deposition apparatus and a film deposition method that are capable of reducing electric power consumption by making use of chemical energy accompanying a catalyst reaction, and that deposit a thin film of metal oxides such as zinc oxide, a thin film of metal nitrides such as gallium nitride and aluminum nitride, and a thin film of silicon nitride on a substrate.

### Means of Solving the Problems

In order to achieve the above aim, a first aspect of the present provides a deposition apparatus including a catalyst reaction apparatus including an introduction part that introduces a first source gas, a catalyst container that contains a catalyst that produces reactive gas from the first source gas introduced from the introduction part, and a reactive gas ejection part that ejects the reactive gas from the catalyst container; a reactive gas separator that allows the reactive gas ejected from the reactive gas ejection part to go therethrough; a substrate supporting part that supports a substrate; and a supplying part that supplies a second source gas that reacts with the reactive gas that passes through the reactive gas separator, so that a film is deposited on the substrate.

A second aspect of the present invention provides a deposition apparatus according to the first aspect, wherein the catalyst reaction apparatus is arranged inside a reaction chamber evacuatable to a reduced pressure, wherein the second source gas is a metal organic compound gas, and wherein the reactive gas separator has a gap in a side surface.

A third aspect of the present invention provides a deposition apparatus according to any one of the first or the second aspect, wherein the reactive gas separator includes plural plate shape members each of which has a through-hole, wherein at least two adjacent plate shape members among the plural plate shape members are arranged so that a gap is formed between the two adjacent plate shape members.

A fourth aspect of the present invention provides a deposition apparatus according to any one of the first through the third aspects, wherein the reactive gas separator includes a cap in the form of funnel, the cap being arranged to provide a gap in relation to the reactive gas ejection part, wherein the cap includes an opening in an apex thereof and has a diameter that becomes larger along an ejection direction of the reactive gas ejected from the reactive gas ejection part.

A fifth aspect of the present invention provides a deposition apparatus according to any one of the first through the fourth aspects, wherein a distal end part of the supplying part that supplies the second source gas is arranged adjacent to the reactive gas separator.

A sixth aspect of the present invention provides a deposition apparatus according to any one of the first through the fifth aspects, further including a shutter that is openable/closable, and arranged between the reactive gas separator and the substrate supporting part.

A seventh aspect of the present invention provides a deposition apparatus according to any, one of the first through the sixth aspects, wherein the introduction part is connected to a source gas supplying part that contains a source gas selected from a mixed gas of H₂ gas and O₂ gas, H₂O₂ gas, hydrazine, and nitride.

An eighth aspect of the present invention provides a deposition apparatus according to any one of the first through the seventh aspects, wherein the catalyst container is blocked by the reactive gas ejection part.

A ninth aspect of the present invention provides a deposition apparatus according to any one of the first through the eighth aspects, wherein the catalyst container is divided into plural compartments by separators each of which has a communication hole, and wherein the catalyst is arranged in each of the plural compartments.

A tenth aspect of the present invention provides a deposition apparatus according to any one of the first through the ninth aspects, wherein the catalyst includes a carrier having an average particle size ranging from 0.05 mm through 2.0 mm, and a catalyst component having an average particle size ranging from 1 nm through nm, the catalyst component being carried by the carrier.

An eleventh aspect of the present invention provides a deposition apparatus according to any one of the first through the tenth aspects, wherein the carrier maybe formed by subjecting porous γ-alumina to a thermal process at 500 through 1200° C. to transform the porous γ-alumina crystal phase into an a-alumina crystal phase while maintaining the surface structure thereof.

A twelfth aspect of the present invention provides a deposition apparatus including a catalyst reaction apparatus including an introduction part that introduces a first source gas; a catalyst container that contains a catalyst that produces a reactive gas from the first source gas introduced from the introduction part; and a reactive gas ejection part that ejects the reactive gas from the catalyst container, the reactive gas ejection part including a diameter reducing part whose inner diameter becomes smaller along an ejection direction of the reactive gas, and a diameter enlarging part whose inner diameter becomes larger along the ejection direction; a substrate support part that supports a substrate; and a supplying part that supplies a second source gas that reacts with the reactive gas ejected from the reactive gas ejection part, so that a film is deposited on the substrate.

A thirteenth aspect of the present invention provides a deposition apparatus according to the twelfth aspect, wherein the catalyst reaction apparatus is arranged in a reaction chamber evacuatable to a reduced pressure, and wherein the second source gas is a metal organic compound gas.

A fourteenth aspect of the present invention provides a deposition apparatus according to the twelfth or the thirteenth aspect, further including a reactive gas separator including a cap in the form of a funnel, the cap being arranged leaving a gap in relation to the reactive gas ejection part, wherein the cap includes an opening at an apex thereof and has a diameter that becomes larger along an ejection direction of the reactive gas ejected from the reactive gas ejection part.

A fifteenth aspect of the present invention provides a deposition apparatus according to the twelfth or the thirteenth aspect, wherein a distal end part of the supplying part that supplies the second source gas is arranged in order to meet the diameter enlarging part.

A sixteenth aspect of the present invention provides a deposition apparatus according to the fourteenth aspect, wherein a distal end part of the supplying part that supplies the second source gas is arranged adjacent to the reactive gas separator.

A seventeenth aspect of the present invention provides a deposition apparatus according to any one of the twelfth through the sixteenth aspects, further including a shutter that is openable/closable and arranged between the reactive gas separator and the substrate supporting part.

An eighteenth aspect of the present invention provides a deposition apparatus according to any one of the twelfth through the seventeenth aspects, wherein the introduction part is connected to a source gas supplying part that contains a source gas selected from a mixed gas of H₂ gas and O₂ gas, H₂O₂ gas, hydrazine, and nitride.

A nineteenth aspect of the present invention provides a deposition apparatus according to any one of the twelfth through the eighteenth aspects, wherein the catalyst container is blocked by the reactive gas ejection part.

A twentieth aspect of the present invention provides a deposition apparatus according to any one of the twelfth through the nineteenth aspects, wherein the catalyst container is divided into plural compartments by separators each of which has a communication hole, and wherein catalyst is arranged in each of the plural compartments.

A twenty-first aspect of the present invention provides a deposition apparatus according to any one of the twelfth through the twentieth aspects, wherein the catalyst includes a carrier having an average particle size ranging from 0.05 mm through 2.0 mm, and a catalyst component having an average particle size ranging from 1 nm through 10 nm, the catalyst component being carried by the carrier.

A twenty-second aspect of the present invention provides a deposition apparatus according to any one of the twelfth through the twenty-first aspects, wherein the carrier may be formed by subjecting porous γ-alumina to a thermal process at 500 through 1200° C. to transform the porous γ-alumina crystal phase into an α-alumina crystal phase while maintaining the surface structure thereof.

A twenty-third aspect of the present invention provides a deposition method including steps of: producing a reactive gas by introducing a first source gas into a catalyst container that contains a catalyst that produces the reactive gas from the first source gas; introducing the reactive gas produced in the catalyst container to a reactive gas separator that allows the reactive gas to flow therethrough and has a gap in a side surface thereof, and supplying a second source gas so that the reactive gas that passes through the reactive gas separator reacts with the second source gas; and depositing a film on a substrate by exposing the substrate to a precursor produced through reaction of the reactive gas and the second source gas.

A twenty-fourth aspect of the present invention provides a deposition method including steps of: producing a reactive gas by introducing a first source gas into a catalyst container that contains a catalyst that produces the reactive gas from the first source gas; introducing the reactive gas produced in the catalyst container to a reactive gas ejection part that includes a diameter reducing part whose inner diameter becomes smaller along an ejection direction of the reactive gas, and a diameter enlarging part whose inner diameter becomes larger along the ejection direction, and supplying a second source gas so that the reactive gas ejected from the reactive gas ejection part reacts with the second source gas; and depositing a film on a substrate by exposing the substrate to a precursor produced through reaction of the reactive gas and the second source gas.

A twenty-fifth aspect of the present invention provides a deposition method including steps of: producing a reactive gas by introducing a first source gas into a catalyst container that contains a catalyst that produces the reactive gas from the first source gas; introducing the reactive gas produced in the catalyst container to a reactive gas ejection part that includes a diameter reducing part whose inner diameter becomes smaller along an ejection direction of the reactive gas, and a diameter enlarging part whose inner diameter becomes larger along the ejection direction; introducing the reactive gas ejected from the reactive gas ejection part to a reactive gas separator including a cap in the form of a funnel, the cap including an opening at an apex thereof and having a diameter that becomes larger along an ejection direction of the reactive gas ejected from the reactive gas ejection part, and introducing a second source gas so that the reactive gas that passes through the reactive gas separator reacts with the second source gas; and depositing a film on a substrate by exposing the substrate to a precursor produced through reaction of the reactive gas and the second source gas.

### EFFECT OF THE INVENTION

According to a deposition apparatus in accordance with an embodiment of the present invention, there are provided a film deposition apparatus and a film deposition method that are capable of reducing electric power consumption by making use of chemical energy accompanying a catalyst reaction, and that deposit a thin film of metal oxides such as zinc oxide, a thin film of metal nitrides such as gallium nitride and aluminum nitride, and a thin film of silicon nitride on a substrate.

### BRIEF DESCRIPTION OF THE DRAWINGS

FIG. 1 illustrates a deposition apparatus according to an embodiment of the present invention.

FIG. 2 is a side view of a catalyst reaction apparatus arranged inside the deposition apparatus of FIG. 1.

FIG. 3 is a schematic cross-sectional view of the catalyst reaction apparatus arranged inside the deposition apparatus of FIG. 1.

FIG. 4 is a side view of a modified example of the catalyst reaction apparatus arranged inside the deposition apparatus of FIG. 1.

FIG. 5 is a schematic cross-sectional view of the catalyst reaction apparatus of FIG. 4.

FIG. 6 is a schematic cross-sectional view of another modified example of the catalyst reaction apparatus arranged inside the deposition apparatus of FIG. 1.

FIG. 7 is a schematic cross-sectional view of a deposition apparatus according to another embodiment of the present invention.

FIG. 8 is a schematic view illustrating a deposition apparatus according to yet another embodiment.

FIG. 9 is an enlarged schematic view of a catalyst reaction apparatus that may be arranged inside the deposition apparatus of FIG. 8.

FIG. 10 is an enlarged schematic view of another catalyst reaction apparatus that maybe arranged inside the deposition apparatus of FIG. 8.

FIG. 11 is an enlarged schematic view of another catalyst reaction apparatus that may be arranged inside the deposition apparatus of FIG. 8.

FIG. 12 illustrates a deposition apparatus according to yet another embodiment of the present invention.

FIG. 13 is a flowchart illustrating a deposition method according to an embodiment of the present invention.

FIG. 14 is a schematic view of a reaction gas ejection nozzle used as a comparative example.

FIG. 15 illustrates an XRD pattern obtained with respect to a ZnO thin film of Example 1.

FIG. 16 illustrates a ω rocking curve obtained with respect to the ZnO thin film of Example 1.

FIG. 17 illustrates an XRD pattern obtained with respect to a ZnO thin film of Example 2.

FIG. 18 illustrates a ω rocking curve obtained with respect to the ZnO thin film of Example 2.

FIG. 19 illustrates an XRD pattern obtained with respect to a ZnO thin film of Comparative Example 1.

FIG. 20 illustrates a ω rocking curve obtained with respect to the ZnO thin film of Comparative Example 1.

### DESCRIPTION OF THE REFERENCE NUMERALS

1, 100, 201, 300 deposition apparatus
2, 202, 302 reaction chamber
102 first reaction chambers
103 second reaction chamber
3, 303, 210A, 211A source gas introduction port
4, 41, 204 reaction gas ejection nozzle
5, 51, 52, 205 catalyst reaction apparatus
6, 206, 306 compound gas introduction nozzle
7, 207, 307 substrate
8, 208, 308 substrate holder
9, 209, 309 shutter
10, 101, 228 reactive gas separator
11, 211, 311 source gas supplying part
12, 212, 312 compound gas supplying part
13, 132, 133, 213 evacuation pipe
14, 142, 143 turbo molecular pump
15, 152, 152 rotary pump
21, 31, 221 catalyst container jacket
22, 222 catalyst reaction container
33 first catalyst reaction containers
34 second catalyst reaction container
23 metal mesh
25 plate shape member
26 pillar
27 press ring
28 funnel shape cap
32 separator
36 communication hole
104 openable/closable door
C catalyst

### MODES(S) FOR CARRYING OUT THE INVENTION

Non-limiting, exemplary embodiments of the present invention will now be described with reference to the accompanying drawings. In the drawings, the same or corresponding reference symbols are given to the same or corresponding members or components. It is to be noted that the drawings are illustrative of the invention, and there is no intention to indicate scale or relative proportions among the members or components. Therefore, the specific size should be determined by a person having ordinary skill in the art in view of the following non-limiting embodiments.

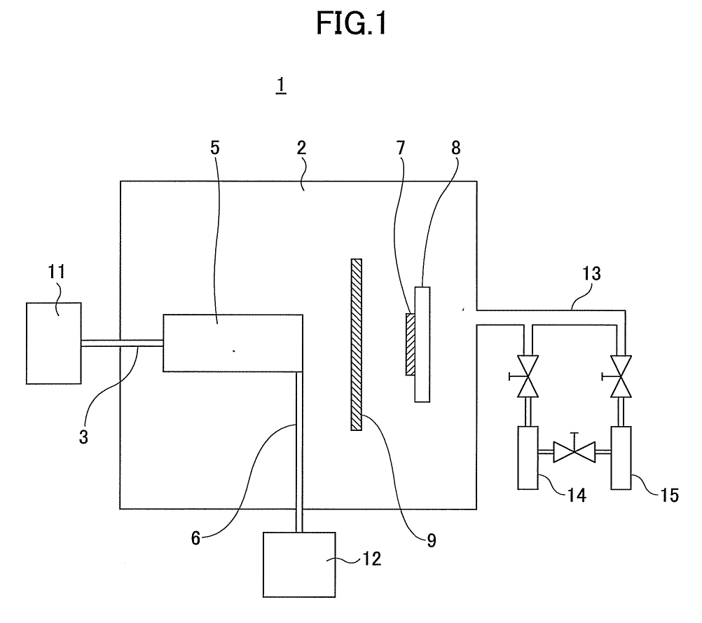

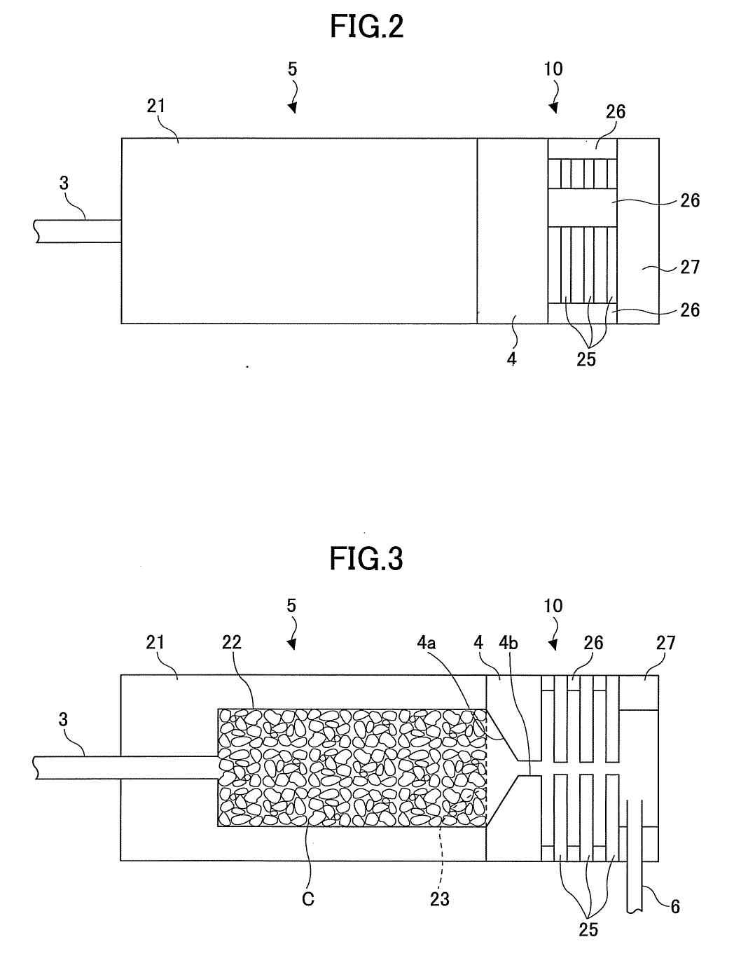

FIG. 1 is a schematic view illustrating a deposition apparatus according to an embodiment of the present invention; FIG. 2 is a side view of a catalyst reaction apparatus arranged inside the deposition apparatus of FIG. 1; and FIG. 3 is a cross-sectional view of the catalyst reaction apparatus of FIG. 2.

Referring to FIG. 1, a deposition apparatus 1 includes a reaction chamber 2 evacuatable to a reduced pressure, a catalyst reaction chamber 5 arranged inside the reaction chamber 2, a source gas supplying part 11 that accommodates a source gas, which includes a liquefied gas, to be supplied to the catalyst reaction chamber 5, a chemical compound introduction nozzle 6 that is connected to a chemical compound supplying part 12 that accommodates a compound as a source of a film to be deposited, and a substrate holder 8 that holds a substrate 7. In addition, the deposition apparatus 1 has an openable/closable shutter 9 between the catalyst reaction apparatus 5 and the substrate holder 8. Moreover, the deposition apparatus 1 has a turbo molecular pump 14 and a rotary pump 15 connected to the reaction chamber 2 via an evacuation pipe 13.

Referring to FIGS. 2 and 3, the catalyst reaction apparatus 5 has a cylinder-shaped catalyst container jacket 21 that is formed of metal such as stainless steel; a catalyst reaction container 22 that is arranged inside the catalyst container jacket 21, formed of a material such as a ceramic material and a metal, has a cylinder shape, and accommodates a catalyst; a source gas introduction port 3 that introduces a source gas to catalyst reaction container 22 from the source gas supplying part 11, and a reaction gas ejection nozzle 4 that ejects a gas from the catalyst reaction container 22.

Inside the catalyst reaction chamber 22, catalyst C formed of a carrier in the form of microparticles carrying a catalyst component in the form of ultra-microparticles is accommodated, in this embodiment. In addition, the catalyst reaction chamber 22 has an opening that opposes a side surface to which the source gas introduction port 3 is connected. A metal mesh 23 that holds the catalyst is arranged in the opening.

The reaction gas ejection nozzle 4 blocks the opening of the catalyst reaction chamber 22, and has a diameter reducing part 4a whose diameter becomes smaller along a direction from the catalyst reaction chamber 22 to the substrate holder 8, and an ejection pipe 4b that is in gaseous communication with the diameter reducing part 4a, thereby ejects the gas from the catalyst reaction chamber 22.

A reactive gas separator 10 is arranged at a distal end of the reaction gas ejection nozzle 4. The reactive gas separator 10 is arranged in an intersecting direction to a direction along which the gas is ejected from the ejection pipe 4b of the reaction gas ejection nozzle 4. The reactive gas separator 10 has plural plate shape members 25, supporting pillars 26 that support the plural plate shape members 25 at predetermined intervals, and a press ring 27 that presses the plural plate shape members 25 along with the supporting pillars 26. With this configuration, the reaction gas ejection nozzle 4 has a first flow passage that is defined by through-holes at the center of the plural plate shape members 25, thereby allowing the gas from the catalyst reaction container 22 to proceed in a straight direction, and a second flow passage that is defined by gaps between the supporting pillars 26 and between the plural plate shape members 25, and branched from the first flow passage. In addition, the through-holes at the center of the plate shape members 25 may have a diameter that is slightly larger than or equal to an inner diameter of the ejection pipe 4b of the reaction gas ejection nozzle 4. Moreover, a distal end portion of the compound gas introduction nozzle 6 is attached to the press ring 27. The compound introduction nozzle 6 is directed toward a direction orthogonal to an ejection direction of the gas that proceeds straight through the through-holes at the center of the plural plate shape members 25.

Incidentally, an entire configuration shown in FIGS. 2 and 3 may be called the catalyst reaction apparatus 5. In addition, this may be applied to a catalyst reaction apparatus in other embodiments described later.

The source gas supplying part 11 (FIG. 1) supplies a source gas that includes a constituent element of a film to be deposited on the substrate 7 and comes in contact with the catalyst (described later) inside the catalyst reaction container 22 to generate a large quantity of heat, thereby generating a reactive gas.

In addition, the compound gas supplying part 12 accommodates a compound (described later) that reacts with the reactive gas obtained by contacting the source gas with the catalyst, thereby becoming precursors of the film to be deposited on the substrate 7.

The shutter 9 arranged between the catalyst reaction apparatus 5 and the substrate holder 8 is typically closed in a predetermined period of time after the source gas is started to be supplied to the catalyst reaction container 22 and opened after the reaction is stabilized. Namely, the catalyst C has a relatively low temperature and has a low generation rate of the reactive gas right after the source gas is supplied to the catalyst reaction container 22, so that a substantial supplying ratio of the reactive gas to the compound gas may not become a predetermined value (such a gas may be called a side product gas, hereinafter). However, because the shutter 9 is closed until a temperature of the catalyst C is stabilized, and then opened, a desired supplying ratio can be realized at an initial stage of the film deposition to the substrate 7. As a result, the film having constant properties can be deposited on the substrate 7.

As stated above, in the deposition apparatus 1 according to the embodiment of the present invention, the reactive gas separator 10 is arranged at the distal end of the reaction gas ejection nozzle 4 of the catalyst reaction apparatus 5, and the reactive gas separator 10 has the plural plate members 25 supported at the predetermined intervals by the supporting pillars 26, each of plate members 25 having the through-hole at the center. The reactive gas having high energy gas generated by causing the source gas introduced into the catalyst reaction apparatus 5 from the reaction gas supplying part 11 to come in contact with the catalyst C proceeds straight through the through-holes at the center of the plural plate shape members 25 (first flow passage), and reacts with the compound gas supplied from the compound gas introduction nozzle 6 and reaches the substrate 7. On the other hand, the reactive gas having relatively low energy flows out to the side though the gaps between the plural plate shape members 25 and between the supporting pillars 26 (second flow passage). Namely, the reactive gas having relatively low energy is evacuated from the reaction chamber 2 without substantially reaching the substrate 7, and thus does not contribute to the film deposition. Therefore, the compound film is deposited on the substrate 7 primarily from the reactive gas having high energy and the compound gas, which reacts with each other, thereby yielding the film having superior properties. In such a manner, the reactive gas separator 10 has a function of extracting a high energy part of the reactive gas from the catalyst reaction apparatus 5.

In addition, because the film is deposited from the compound gas and the reactive gas having high energy originated from the catalyst reaction, the substrate 7 is not necessarily heated to a temperature that allows the source gas and a reaction gas to react with the source gas, thereby saving electric power required to heat the substrate 7.

Moreover, because the compound gas introduction nozzle 6 is attached to the press ring 27 of the reactive gas separator 10, the compound gas can substantially completely react with the reactive gas. Therefore, un-reacted compound gas is impeded from directly reaching the substrate 7 and being incorporated into the film, thereby improving the film properties.

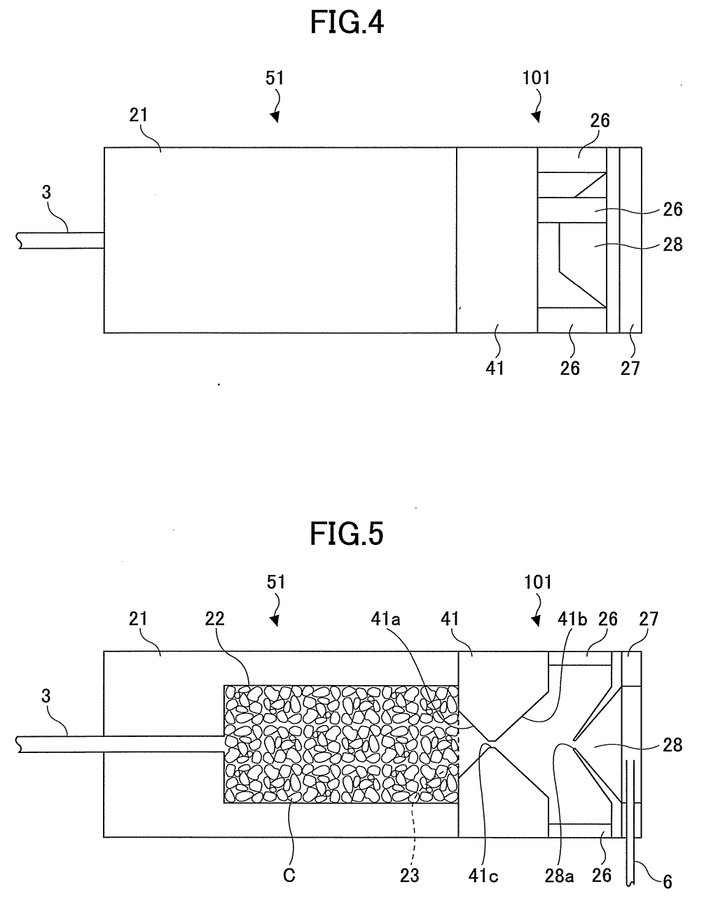

FIG. 4 is a side view illustrating a modified example of the catalyst reaction apparatus used in the deposition apparatus 1 according to another embodiment. FIG. 5 is a cross-sectional view of the catalyst reaction apparatus of FIG. 4.

Referring to FIGS. 4 and 5, a catalyst reaction apparatus 51 is different from the catalyst reaction apparatus 5 in that the catalyst reaction apparatus 51 has a reaction gas ejection nozzle 41 in the place of the reaction gas ejection nozzle 4 of the catalyst reaction apparatus 5 and a reactive gas separator 101 is arranged at the distal end portion of the reaction gas ejection nozzle 41, and is the same as the catalyst reaction apparatus 5 in other configurations.

The reaction gas ejection nozzle 41 has a diameter reducing part 41a whose diameter becomes smaller like a funnel along a flow direction of the reactive gas flowing out from the catalyst reaction container 22 through the metal mesh 23, and a diameter enlarging part 41b whose diameter becomes greater like an inverse funnel. The diameter reducing part 41a and the diameter enlarging part 41b are in gaseous communication with each other at a minimum diameter part 41c, and an inner diameter of the minimum diameter part 41c may preferably be within a range from about 0.1 mm through about 1.0 mm. A broadening angle of the diameter reducing part 41a may preferably be within a range from about 5.0° through about 170°, and more preferably within a range from about 10° through about 120°. A broadening angle of the diameter enlarging part 41b may preferably be within a range from about 2.0° through about 170°, and more preferably within a range from about 3.0° through about 120°. A combination of the broadening angles of the diameter reducing part 41a and the diameter enlarging part 41b are arbitrarily determined.

The reactive gas separator 101 has a funnel shape cap 28 whose diameter becomes greater toward the substrate holder 8 and that has a hole 28a at the apex, a press ring 27 that presses the funnel shape cap 28, and supporting pillars 26 that attaches the press ring 27 onto the reaction gas ejection nozzle 41. With such a configuration, the funnel shape cap 28 is away from the reaction gas ejection nozzle 41, leaving a gap between them. A broadening angle of the diameter reducing part 41a may preferably be within a range from about 30° through about 70°, and more preferably within a range from about 40° through about 60°. In addition, a diameter of the hole 28a may preferably be within a range from about 100% through 5000% in relation to the inner diameter of the minimum diameter part 41c of the reaction gas ejection nozzle 4. Because the minimum diameter part 41 has the inner diameter ranging from about 0.1 mm through about 1.0 mm, as stated above, the diameter of the hole 28a may be within a range from about 0.1 mm through about 50 mm. Incidentally, a distal end of the compound gas introduction nozzle 6 is attached to the press ring 27 of the reactive gas separator 101. The compound introduction nozzle 6 is directed toward a direction orthogonal to an ejection direction of the gas that is ejected through the hole 28a of the funnel shape cap 28 from the reactive gas ejection nozzle 41.

According to the above configuration, when a large part of the reactive gas generated in the catalyst reaction container 22 is ejected from the diameter reducing part 41a to the diameter enlarging part 41b through the metal mesh 23, the reactive gas passes straight as a high speed flux having high (translatory) energy through the hole 28a of the funnel shape cap 28, reacts with the compound gas from the distal end of the compound gas introduction nozzle 6, and reaches the substrate 7. On the other hand, a part of the reactive gas that does not acquire sufficiently high energy among the reactive gas from the catalyst reaction container 22 expands outward, for example, along an inner surface of the diameter enlarging part 41b, reaches an outer surface of the funnel shape cap 28, and flows out laterally through the gaps between the reaction gas ejection gas nozzle 41 and the funnel shape cap 28 and between the supporting pillars 26. The reactive gas that flows through the gaps are evacuated from the reaction chamber 2 (see FIG. 1) substantially without reaching the substrate 7. Therefore, the film is deposited on the substrate 7 primarily from the reactive gas having high energy and the compound gas that reacts with such a reactive gas. Namely, the catalyst reaction apparatus 51 according to this modified example can provide the same effects as those of the catalyst reaction apparatus 5 described above.

As stated above, the part of the reactive gas that does not acquire sufficiently high energy substantially cannot reach the substrate 7, even if the reactive gas separator 101 (or the funnel shape cap 28) is attached to the reaction gas ejection nozzle 41, because such a reactive gas expands outward. Therefore, the same effect as above can be provided. For the sake of convenience, the catalyst reaction apparatus 51 that does not have the reactive gas separator 101 is called a catalyst reaction apparatus 51A.

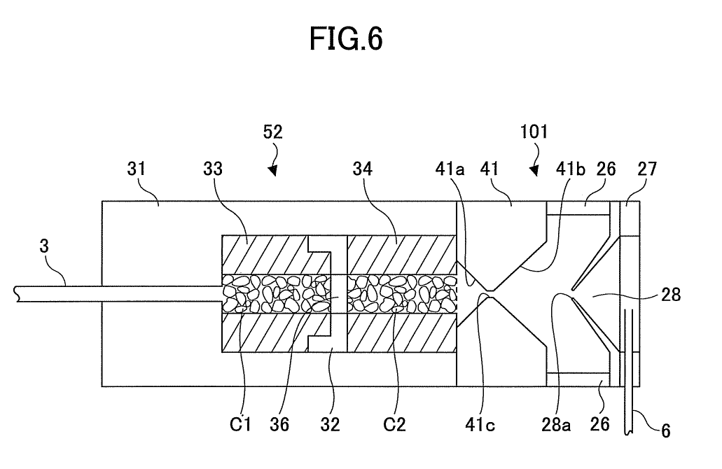

FIG. 6 is a schematic cross-sectional view of another modified example of the catalyst reaction apparatus used in the deposition apparatus 1 according to an embodiment of the present invention.

As shown, a catalyst container jacket 31 is separated into two chambers by a separator 32 having a communication hole 36 at the center; a first catalyst reaction container 33 is arranged in one chamber; and a second catalyst reaction container 34 is arranged in the other chamber, in a catalyst reaction apparatus 52. With such a configuration, two-stage catalyst reactions can take place in the catalyst reaction apparatus 52.

For example, when a hydrazine gas is used in order to deposit a metal nitride thin film, a hydrazine decomposition catalyst C1 that decomposes the hydrazine into an ammonia component may be filled in the first catalyst reaction container 33, and an ammonia decomposition catalyst C2 that further decomposes the ammonia into radicals maybe filled in the second catalyst reaction container 34.

As such a hydrazine decomposing catalyst C1 filled in the first catalyst reaction container 33, a carrier in the form of microparticles of, for example, alumina, silica, zeolite or the like carrying iridium ultra-microparticles of 5 through about 30 wt. % may be used. In addition, the ammonia decomposing catalyst C2 filled in the second catalyst reaction container 34, the same carrier carrying ruthenium ultra-microparticles of 2 through 10 wt. % may be used.

Such a two-stage decomposition reaction may proceed as follows:

2N₂H₄→2NH₃+H*₂+N*₂ (1)

NH₃→NH*+H*₂, NH*₂+H (2)

Incidentally, while the catalyst reaction apparatus 52 shown in FIG. 6 is provided with the reaction gas ejection nozzle 41 and the reactive gas separator 101, the catalyst reaction apparatus 52 may be provided with the reaction gas ejection nozzle 4 and the reactive gas separator 10 instead. Alternatively, only the reaction gas ejection nozzle 41 may be connected to the catalyst reaction apparatus 52. In other words, the catalyst container jackets 21 of the catalyst reaction apparatuses 5, 51A may be separated into two chambers by the separator 32 having the communication hole 35; the first catalyst reaction container 33 is arranged in one chamber; and the second catalyst reaction container 34 is arranged in the other chamber.

In addition, the catalyst of the same kind may be filled in the catalyst reaction containers 33, 34. In addition, the catalyst container jacket 31 (21) may be divided into three or more chambers to provide three or more catalyst reaction containers, and the catalyst reaction may be made to occur in three or more stages.

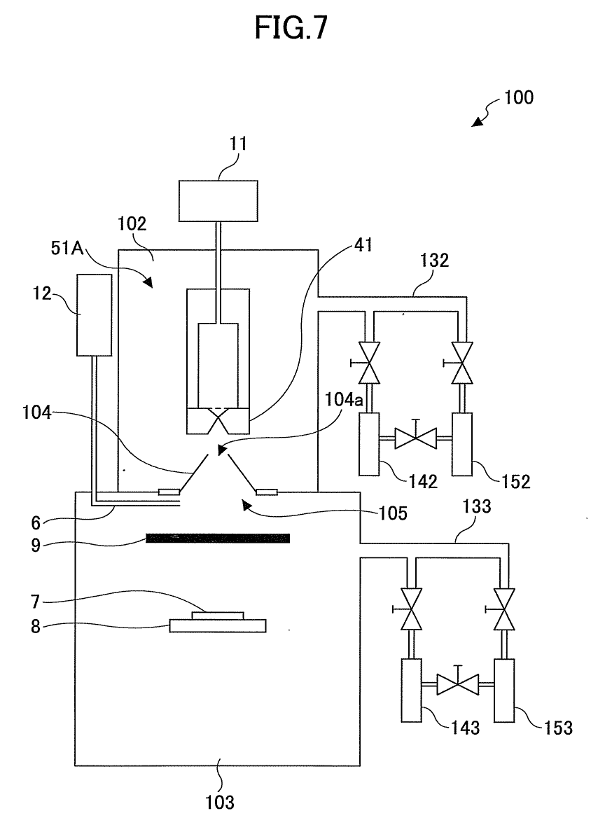

FIG. 7 is a schematic view of a deposition apparatus according to another embodiment of the present invention.

A deposition apparatus 100 according to this embodiment has a first reaction chamber 102 and a second reaction chamber 103 coupled to the first reaction chamber 102. As shown, the first reaction chamber 102 accommodates a catalyst reaction apparatus 51A, and the second reaction chamber 103 accommodates a substrate holder 8 that supports the substrate 7. The first reaction chamber 102 and the second reaction chamber 103 are in gaseous communication with each other via an opening 105, and the opening is provided with an open/close door 104 on the side of the first reaction chamber 103. The open/close door 104 has a shape of a funnel, and an apex opening 104a is aligned with the reaction gas ejection nozzle 41 of the catalyst reaction apparatus 51A. Incidentally, the open/close door 104 may be configured so that a diameter of the apex opening 104a and a side surface angle are adjustable.

In addition, the first reaction chamber 102 is connected to a turbo molecular pump 142 and a rotary pump 152 via an evacuation pipe 132. The second reaction chamber 103 is connected to a turbo molecular pump 143 and a rotary pump 153 via an evacuation pipe 133. With these configurations, a pressure inside the first reaction chamber 102 and a pressure inside the second reaction chamber 103 can be controlled separately.

The catalyst reaction apparatus 51A arranged in the first reaction chamber 102 is connected to the source gas supplying part 11 arranged outside the first reaction chamber 102. In addition, the compound gas introduction nozzle 6 connected to the compound gas supplying part 12 arranged outside the first reaction gas chamber 102 is arranged near the open/close door 14 in the second reaction chamber 103. The openable/closable shutter 9 is provided between the open/close door 104 and the substrate supporting holder 8.

In the deposition apparatus 100 according to this embodiment, when the source gas is supplied to the catalyst reaction apparatus 51A from the source gas supplying part 11, an exothermal reaction takes place between the source gas and the catalyst in the catalyst reaction apparatus 51, thereby generating the reactive gas, and the reactive gas is ejected from the reaction gas ejection nozzle 41. In this case, a large part of the reactive gas passes straight as a high speed flux having high (translatory) energy through the apex opening 104a of the open/close door 104, reacts with the compound gas from the distal end of the compound gas introduction nozzle 6, and reaches the substrate 7. On the other hand, a part of the reactive gas that does not acquire sufficiently high energy among the reactive gas expands outward, for example, along the diameter enlarging part 41b of the reaction gas ejection nozzle 41, reaches an outer surface of the open/close door 104, circulates inside the first reaction chamber 102, and is evacuated by the turbo molecular pump 142 via the evacuation pipe 132. Namely, the reactive gas having relatively low energy substantially cannot reach the second reaction chamber 103. Therefore, the film having excellent properties is deposited on the substrate 7 from the reactive gas having high energy and the compound gas that reacts with such a reactive gas, even in the deposition apparatus 100.

In addition, because the deposition apparatus 100 is configured of the first reaction chamber 102 and the second reaction chamber 103 that can be controlled in terms of their inner pressures, film deposition conditions of the film can be more sensitively adjusted.

Incidentally, while the deposition apparatus 100 according to this embodiment has the catalyst reaction apparatus 51A, the deposition apparatus 100 may have the catalyst reaction chamber 5, 51, or 52 instead. Alternatively, the deposition apparatus 100 may have a catalyst reaction apparatus 205 described later.

Here, the films that can be deposited by the deposition apparatuses according to the embodiments of the present invention, the source gases, or the like are exemplified.

(Nitride Films)

When nitride films are deposited on the substrate 7, the source gas to be introduced into the catalyst reaction apparatus 5 or the like may be hydrazine gas, nitride gas, or the like.

As nitrides to be deposited on the substrate 7, there may be cited, for example but not limited to, metal nitrides such as gallium nitride, aluminum nitride, indium nitride, gallium indium nitride (GaInN), gallium aluminum nitride (GaAlN), gallium indium aluminum nitride (GaInAlN), and a semimetal nitride. The semimetal nitride includes, for example, a semiconductor nitride, and an example of the semiconductor nitride is silicon nitride.

When the metal nitride films are deposited, for example but not limited to, a metal organic compound gas to be used when depositing a metal nitride in a conventional CVD method may be used as a metal compound gas serving as the source gas. As such a metal organic compound, there may be cited, for example but not limited to, an alkyl compound, an alkenyl compound, a phenyl compound, an alkyl phenyl compound, an alkoxide compound, a di-pivaloyl methane compound, a halogen compound, an acetylacetonate compound, an EDTA compound, or the like of various metals.

As a preferable metal organic compound, there may be cited, for example but not limited to, an alkyl compound and an alkoxide compound of various metals. Specifically, trimethyl gallium, triethyl gallium, trimethyl aluminum, triethyl aluminum, trimethyl indium, triethyl indium, trietoxy gallium, triethoxy aluminum, triethoxy indium or the like.

When depositing a gallium nitride film on a substrate, a trialkyl gallium such as trimethyl gallium and triethyl gallium is preferably used as the source material, and a porous alumina in the form of microparticles carrying ruthenium ultra-microparticles is preferably used as the catalyst.

In addition, a metal compound gas serving as the source material of a metal nitride film may be an inorganic metal compound gas, not being limited to the metal organic compound gas. The inorganic metal compound may be, for example but not limited to, a halogen compound gas except for the metal organic compound. Specifically, the inorganic metal compound gas may be a chloride gas such as gallium chloride (GaCl, GaCl₂, GaCl₃).

When depositing a silicon nitride film on a substrate, for example but not limited to, a silicon hydrogen compound, a silicon halogen compound, an organic silicon compound may be used as a silicon source. As an example of the silicon hydrogen compound, there are silane and disilane. As an example of the silicon halogen compound, there are silicon chloride compounds such as dichlorosilane, trichlorosilane, and tetrachlorosilane. As an example of the organic silicon compound, there are tetraethoxysilane, tetramethoxysilane, and hexamethyldisilazane.

(Oxide Films)

When oxide films are deposited on the substrate 7, the source gas to be introduced to the catalyst reaction apparatus 5 or the like may be, for example, a mixed gas of H₂ gas and O₂ gas, or H₂O₂ gas.

As the oxide films deposited on the substrate 7, there may be cited, for example but not limited to, metal oxide films such as titanium oxide, zinc oxide, magnesium oxide, yttrium oxide, sapphire, Sn:In₂O₃ (Indium Tin Oxide: ITO). In addition, a metal oxide where tin (Sn) is substituted with zinc (Zn) maybe also cited.

As a metal organic compound gas serving as a source material of the metal oxide compound thin film, for example but not limited to, any metal organic compound that is used when depositing a metal oxide in a conventional CVD method may be used. As such a metal organic compound, there may be cited, for example but not limited to, an alkyl compound, an alkenyl compound, a phenyl compound, an alkyl phenyl compound, an alkoxide compound, a di-pivaloyl methane compound, a halogen compound, an acetylacetonate compound, an EDTA compound, or the like of various metals. Incidentally, the source material of the metal oxide thin film may be an inorganic metal compound gas such as a halogen compound, except for the metal organic compound gas. Specifically, a zinc chloride (ZnCl₂) or the like is cited.

As a preferable metal organic compound, there may be cited, for example but not limited to, an alkyl compound and alkoxide compound of various metals. Specifically, dimethyl zinc, diethyl zinc, trimethyl aluminum, triethyl aluminum, trimethyl indium, triethyl indium, trimethyl gallium, triethyl gallium, trietoxy aluminum or the like may be cited.

When the zinc oxide film is deposited on the substrate 7, the dialkyl zinc such as dimethyl zinc and diethyl zinc is preferably used as the source material, and alumina in the form of microparticles carrying platinum ultra-microparticles is preferably used as the catalyst.

(Catalyst)

As an example of the catalyst C accommodated in the catalyst reaction apparatus 5 or the like, there maybe cited powders or microparticles, having an average particle size of 0.1 mm through 0.5 mm, of metals such as copper, iridium, ruthenium, and platinum.

In addition, as another example of the catalyst C accommodated in the catalyst reaction apparatus 5 or the like, there may be cited catalyst formed of a carrier in the form of microparticles having an average particle size of 0.05 through 2.0 mm, which carries a catalyst component in the form of ultra-microparticles having an average particle size of 1 through 10 nm. In this case, as an example of the catalyst component, there may be cited metals such as copper, iridium, ruthenium, and platinum. As an example of the carrier, there may be cited metal oxide microparticles of zinc oxide, silicon oxide, zirconium oxide, aluminum oxide, namely, microparticles of oxide ceramic materials, zeolite, or the like. An especially preferable carrier may be formed by subjecting porous γ-alumina to a thermal process at 500 through 1200° C. to transform the porous γ-alumina into an α-alumina crystal phase while maintaining the surface structure thereof. With such a thermal process, because the surface structure is maintained, while a large part of the porous γ-alumina is transformed into the α-alumina crystal phase, which has high thermal resistance, the carrier having a large superficial area is obtained. With this, the superficial area on which the catalyst component carried by the carrier and the source gas come into contact with each other, thereby facilitating formation reaction of the reactive gas.

As the catalyst C preferably used for fabricating the metal nitride thin films, there may be cited the above aluminum oxide carrier that carries nanoparticles of ruthenium or iridium of 1 through 30 wt. % (for example, 10 wt. % Ru/α-Al₂O₃ catalyst), or the like.

As the catalyst C preferably used for fabricating the metal oxide thin films, there may be cited the aluminum oxide carrier that carries nanoparticles of platinum nanoparticles, especially, a carrier obtained by subjecting porous γ-alumina to a thermal process at 500 through 1200° C. to transform the porous γ-alumina into an α-alumina crystal phase while maintaining the surface structure thereof, the carrier carrying platinum of 1 through 20 wt.% (e.g., 10 wt. % Pt/γ-Al₂O₃ catalyst), or the like.

Moreover, the carrier may have a shape having a lot of pores, such as a sponge, or a bulk shape such as a shape having through-holes, such as a honeycomb or the like. In addition, the catalyst materials such as copper, iridium, ruthenium, and platinum carried by the carrier may have a film-like shape, not being limited to microparticles. In order to certainly obtain the effect in this embodiment, a superficial area of the catalyst material is preferably larger. Therefore, because the superficial area of the catalyst material can be larger when the film of the catalyst material is formed on the surface of the carrier, the same effect as the catalyst in the form of microparticles can be provided.

In addition, as the substrate, one selected from metal, metal nitride, glass, ceramic materials, semiconductors, and plastic may be used.

As a preferable substrate, there may be cited a compound semiconductor single crystalline substrate, a single crystalline substrate as typified by silicon or the like, an amorphous substrate as typified by glass, an engineering plastic substrate such as polyimide, or the like.

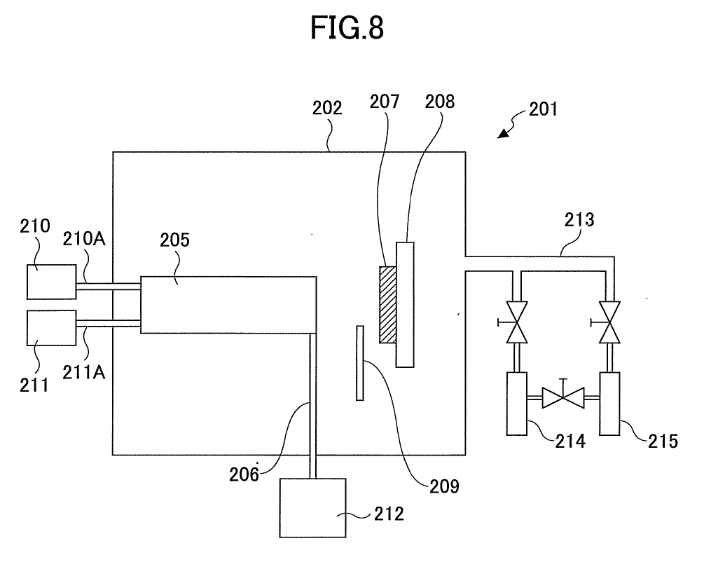

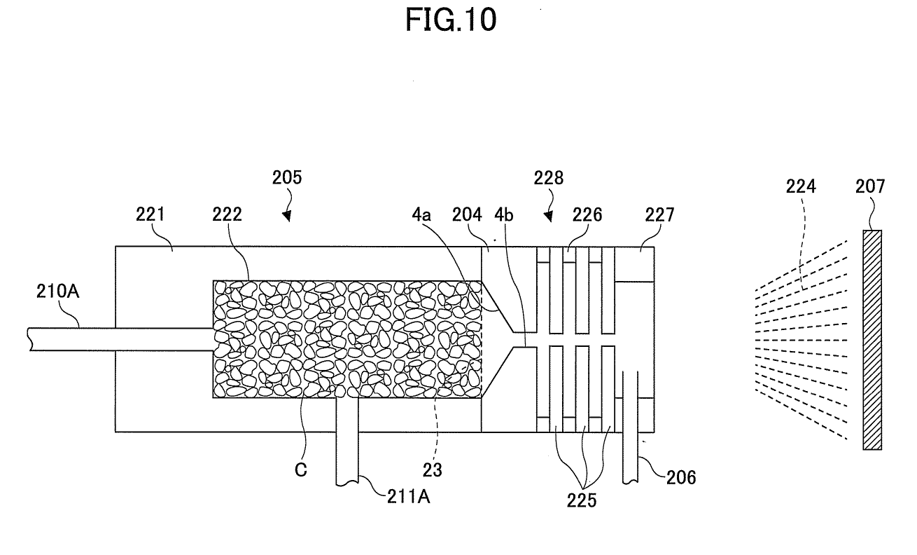

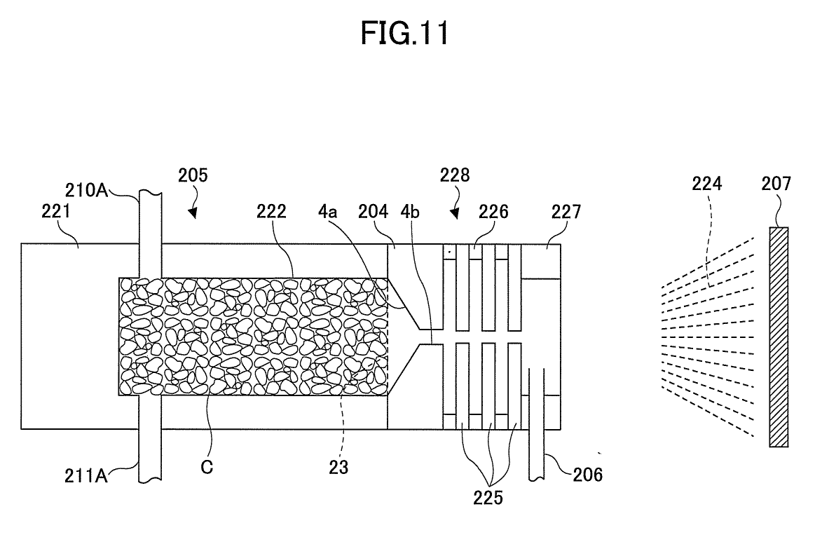

Next, a deposition apparatus according to yet another embodiment of the present invention is explained with reference to FIGS. 8 through 11.

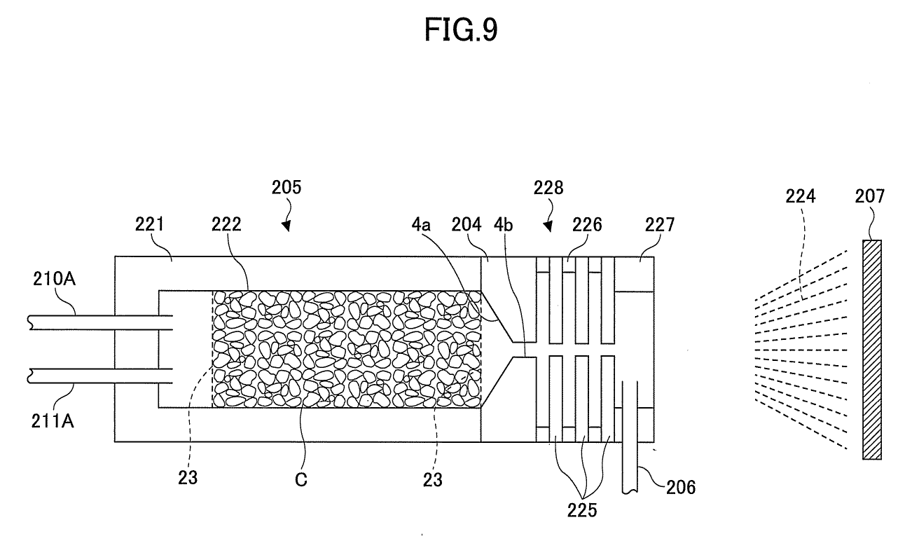

FIG. 8 is a schematic view illustrating a deposition apparatus according to yet another embodiment of the present invention, and FIG. 9 is an enlarged schematic view of a catalyst reaction apparatus arranged inside the deposition apparatus.

A deposition apparatus 201 has a reaction chamber 200 evacuatable to a reduced pressure. Inside the reaction chamber 200, a catalyst reaction apparatus 205, a compound gas introduction nozzle 206 connected to a compound gas supplying part 212, and a substrate holder 208 that supports a substrate 207 are arranged. The reaction chamber 200 is connected to a turbo molecular pump 214 and a rotary pump 215 via an evacuation pipe 213. Incidentally, even in the deposition apparatus 201 shown in FIG. 8, an openable/closable shutter 209 may be provided between the catalyst reaction apparatus 205 and the substrate 207 (the opened shutter is illustrated in the drawing), so that the side product gas is shut off by closing the shutter 209 at an early stage of reaction.

Referring to FIG. 9, the catalyst reaction apparatus 205 includes a cylinder-shaped catalyst container jacket 221 that is formed of metal such as stainless steel, and a catalyst reaction container 222 that is arranged inside the catalyst container jacket 221, formed of a material such as a ceramic material and a metal, has a cylinder shape, and accommodates catalyst. In addition, source gas introduction ports 210A, 211A that go through the catalyst container jacket 221 are connected to one side surface of the catalyst reaction container 222.

Inside the catalyst reaction container 222, the catalyst C formed of a carrier in the form of microparticles carrying a catalyst component in the form of ultra-microparticles is accommodated. In addition, the catalyst reaction container 222 has an opening that opposes a side surface to which the source gas introduction ports 210A, 211A are connected. The metal mesh 23 that holds the catalyst is arranged in the opening. Moreover, another metal mesh 23 is arranged facing distal ends of the source gas introduction ports 210A, 211A in order to keep the catalyst C away from the source gas introduction ports 210A, 211A in the catalyst reaction container 222.

A reactive gas ejection nozzle 204 is arranged at an opening end part of the catalyst reaction chamber 222, and a reactive gas separator 228 is arranged at a distal end of the reactive gas ejection nozzle 204. The reactive gas ejection nozzle 204 has the same configuration of the reactive gas ejection nozzle 4, and the reactive gas separator 228 has the same configuration of the reactive gas separator 4. In addition, a distal end part of the compound gas introduction nozzle 206 is fixed to the press ring 227. The compound gas introduction nozzle 206 is directed to a direction orthogonal to an ejection direction of the gas ejected toward the reactive gas separator 228 from the reactive gas ejection nozzle 204.

Referring again to FIG. 8, a source gas introduction port 210A is connected to the first source gas supplying part 210, and the source gas introduction port 211A is connected to the second source gas supplying part 211. When an oxide film, for example, is deposited in the deposition apparatus 201 according to this embodiment, the first source gas supplying part 210 may be configured so that H₂ gas, for example, is supplied to the catalyst reaction container 222 of the catalyst reaction apparatus 205, and the second source gas supplying part 211 may be configured so that O₂ gas, for example, is supplied to the catalyst reaction container 222 of the catalyst reaction apparatus 205. When configured in such a manner, the same effect as a case where the mixed gas of the H₂ gas and the O₂ gas is used can be obtained.

In addition, by separately introducing the H₂ gas and the O₂ gas, a back fire (fire caused in a catalyst reaction chamber at the time when H₂O is generated is caught on the H₂O source gas flowing upstream relative to the catalyst reaction chamber) that may take place when a mixed gas of the H₂ gas and the O₂ gas is introduced into a catalyst reaction chamber can be suppressed.

In addition, when a nitride film, for example, is deposited in the deposition apparatus 201 according to this embodiment, the first source gas supplying part 210 may be configured so that a nitrogen supplying gas, for example, is supplied to the catalyst reaction container 222 of the catalyst reaction apparatus 205, and the second source gas supplying part 211 may be configured so that a reaction adjusting gas, for example, is supplied to the catalyst reaction container 222 of the catalyst reaction apparatus 205. As the reaction adjusting gas, a nitrogen containing gas such as ammonia and nitrogen may be used. Moreover, the reaction adjusting gas may be an inert gas such as helium (He) and argon (Ar), and hydrogen (H₂) gas.

For example, a concentration of the hydrazine inside the catalyst reaction container 221 can be adjusted by introducing the hydrazine gas serving as the nitrogen supplying gas and the ammonia gas serving as the reaction adjusting gas into the catalyst reaction container 221. While decomposition of hydrazine due to a catalyst in the form of microparticles accompanies a large quantity of heat, a temperature inside the catalyst reaction container 221 can be adjusted by adjusting the concentration of hydrazine with ammonia. In addition, a part of the ammonia gas may be decomposed by the catalyst C in the catalyst reaction container 221, and thus becomes a reactive gas that is to react with the metal compound gas.

Incidentally, the concentration of hydrazine can be adjusted in the same manner by introducing the hydrazine serving as the nitrogen supplying gas and the N₂ serving as the reaction adjusting gas into the catalyst reaction container 221.

Even in the deposition apparatus 201 according to this embodiment, apart of the reactive gas that has high energy out of the reactive gas generated in the catalyst reaction apparatus 205 proceeds straight from the ejection pipe 4b of the reactive gas ejection nozzle 204 through through-holes at the center of plural plate shape members 225, reacts with the compound gas supplied from the compound gas introduction nozzle 206, and reaches the substrate 207. On the other hand, the reactive gas having relatively low energy flows out to the side though the gap between the plural plate shape members 225 and the gap between the supporting pillars 226. Namely, the reactive gas having relatively low energy is evacuated from the reaction chamber 202 without substantially reaching the substrate 207, and thus does not contribute to the film deposition. Namely, because a precursor gas 224 (FIG. 9) generated through the gas phase reaction of the reactive gas having high energy reacts and the compound gas reaches the substrate 207 and a compound film is deposited on the substrate 207, the film having superior properties is obtained.

Moreover, in the deposition apparatus 201 according to this embodiment, because not only the first source gas supplying part 210 is connected to the catalyst reaction apparatus 205 via the source gas introduction port 210A (FIG. 9) but also the second source gas supplying part 211 is connected to the catalyst reaction apparatus 205 via the source gas introduction port 211A (FIG. 9), ammonia or N₂, for example, serving as the reaction adjusting gas can be introduced along with the hydrazine serving as the nitrogen supplying gas into the catalyst reaction apparatus 205. With this, an amount of the reactive gas generated through decomposition of the hydrazine by the catalyst C, namely, an amount of the reactive gas supplied to the substrate 207 can be adjusted. As a result, it becomes possible to improve properties of the nitride film deposited on the substrate 207. Moreover, because an amount of heat generated through decomposition of hydrazine can be adjusted by adjusting the concentration of hydrazine, and thus a temperature of not only the catalyst C but also the reactive gas, it becomes possible to improve properties of the nitride film deposited on the substrate 207. In other words, according to this embodiment, usage of the reaction adjusting gas allows expansion of a process window, and thus it becomes possible to obtain a high quality nitride film through optimization of deposition conditions.

Incidentally, the catalyst reaction container 221 in the catalyst reaction apparatus 205 shown in FIGS. 8 and 9 may have the first reaction container 33 and the second catalyst reaction container 34 as shown in FIG. 6.

In addition, while the source gas introduction ports 210A and 211A are connected in positions of the catalyst reaction apparatus 205 that oppose the reaction gas ejection nozzle 204 to the catalyst reaction apparatus 205 as shown in FIG. 9 in this embodiment, one of the source gas introduction ports 210A and 211A may be connected in a position of the catalyst reaction apparatus 205 that opposes the reaction gas ejection nozzle 204 to the catalyst reaction apparatus 205 and the other one may be connected to a position corresponding to a side surface of the catalyst reaction apparatus 205 in another embodiment. Moreover, the source gas introduction ports 210A and 211A may be connected to positions corresponding to a side surface of the catalyst reaction apparatus 205 in yet another embodiment. Even with these configurations, the above effect can be demonstrated.

In addition, the source gas, the compound gas, the catalyst, and the substrate, which have been cited above, may be arbitrarily selected, thereby depositing the oxides and the nitrides, which have been cited above, on the substrate in this embodiment.

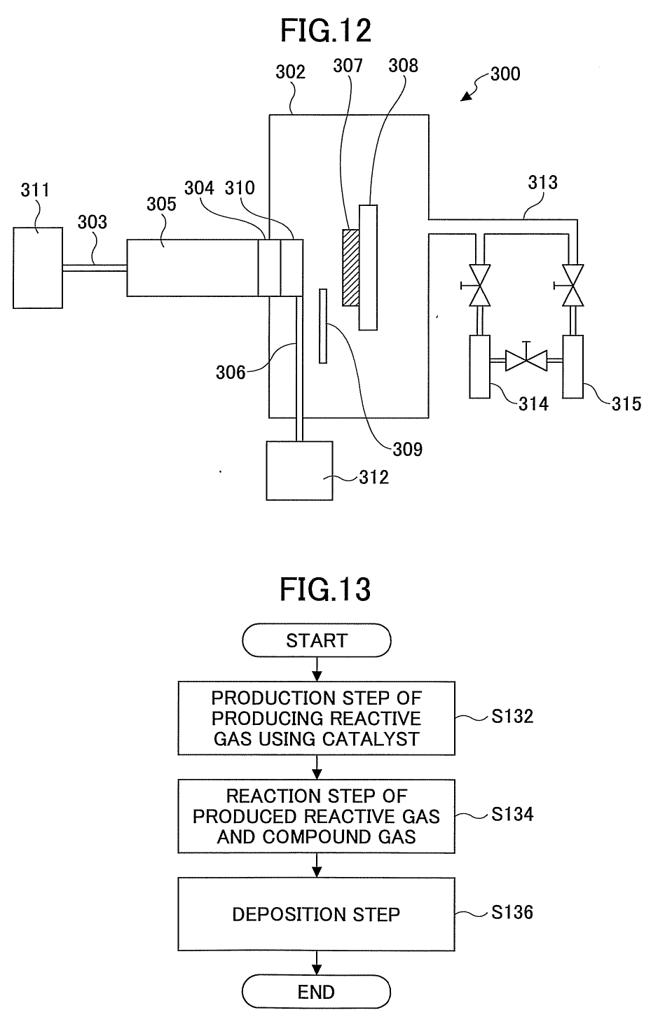

The catalyst reaction apparatuses 5, 51, 51A, 52, 205, which are arranged inside the reaction chamber 2 or the like in any one of the above embodiments, may be arranged outside the reaction chamber 2 or the like. Such a configuration is shown in FIG. 12. As shown, a catalyst reaction apparatus 305 having the same configuration as the catalyst reaction apparatus 5 shown in detail in FIG. 3 is arranged outside a deposition chamber 302, and a reaction gas ejection nozzle 304 of the catalyst reaction apparatus 305 is inserted into the reaction chamber 302 in an airtight manner. In addition, a source gas supplying part 311 is connected via a source gas introduction port 303 to an end part of the catalyst reaction apparatus 305 that opposes the reaction gas ejection nozzle 304 of the catalyst reaction apparatus 305. With this, the source gas is introduced into a catalyst reaction container (refer to the catalyst reaction container 22 of FIG. 3) inside the catalyst reaction apparatus 305 from the source gas supplying part 311. A reactive gas separator 310 arranged at a distal end part of the reaction gas ejection nozzle 304 is positioned inside the reaction chamber 302 that is evacuatable to a reduced pressure. The reactive gas separator 310 has the same configuration as the reactive gas separator 10 described above. In addition, a compound gas introduction nozzle 306 connected to a compound gas supplying part 312 that supplies a compound serving as a source material of a film to be deposited on the substrate 307 is connected to a press ring (refer to FIG. 3) of the reactive gas separator 310. Moreover, a substrate holder 308 that supports the substrate 307 is arranged inside the reaction chamber 302. Furthermore, the reaction chamber 302 is connected to the turbo molecular pump 314 and the rotary pump 315 via an evacuation pipe 313. Incidentally, even in the deposition apparatus 300 shown in FIG. 12, an openable/closable shutter 309, which is in an open state in the drawing, is provided between the catalyst reaction apparatus 305 and the substrate 307, so that a side reaction gas may be blocked by closing the shutter 309 at an initial stage of the reaction. Even in such a configuration, the same effect as the above embodiments can be demonstrated.

Incidentally, the source gas, the compound gas, the catalyst, and the substrate, which have been cited above, may be arbitrarily selected, thereby depositing the oxides and the nitrides, which have been cited above, on the substrate even in the deposition apparatus 300. In addition, the catalyst reaction apparatus 305, which has the same configuration as the catalyst reaction apparatus 5 in this embodiment, may have the same configuration as the catalyst reaction apparatuses 51, 51A, 52, 205 in other embodiments.

Next, procedures of depositing (1) a metal oxide thin film and (2) a metal nitride thin film employing the deposition apparatus according to an embodiment of the present invention are explained with reference to FIG. 13. While film deposition procedures employing the deposition apparatus 1 having the catalyst reaction apparatus 5 are explained in the following, the films can be deposited even when the other deposition apparatus described above are used. In addition, the source gas, the compound gas, the catalyst, and the substrate, which have been cited above, may be naturally arbitrarily selected.

(1) Deposition of a Metal Oxide Thin Film

When the H₂O gas source composed of a mixed gas of H₂ gas and O₂ gas (or H₂O₂ gas) filled in the source gas supplying part 11 of the deposition apparatus 1 of FIG. 1 is introduced into the catalyst reaction apparatus 5 from the source gas introduction port 3, a chemical combination reaction of H₂ gas and O₂ gas takes place due to the catalyst in the form of microparticles, and thus H₂O is produced. Because this reaction generates a large amount of heat, the produced H₂O is heated by the reaction to become H₂O gas at temperatures of about 100° C. through about 1700° C., preferably about 600° C. through about 1700° C., thereby acquiring high reactivity (S132 of FIG. 13) The H₂O gas is ejected to the reactive gas separator 10 through the reactive gas ejection nozzle 4 from the catalyst reaction container 22. At this time, a part of the H₂O gas having sufficiently high energy is vigorously ejected toward the substrate held by the substrate holder 8 through the through-holes of the plate shape members 25 of the reactive gas separator 10. The ejected H₂O gas reacts with the compound gas supplied through the compound gas introduction nozzle 6 from the compound gas supplying part 12 (S134), and thus a film composed of an oxide of the compound is deposited on the substrate 7 (S136). On the other hand, a part of the H₂O gas having a relatively low energy among the H₂O gas that reaches the reactive gas separator 10 from the reactive gas ejection gas nozzle 4 deviates its direction from a straight direction along which the gas proceeds straight through the through-holes of the plate shape members 25, hits the plate shape member 25, flows to the side out from the reactive gas separator 10 through the gaps between the plate shape members 25, and thus no longer contributes to the film deposition. Therefore, the film of the compound is deposited on the substrate 7 from the H₂O gas having high energy and the compound gas that reacts with such a H₂O gas, and thus the film having excellent properties is obtained.

(2) Deposition of a Metal Nitride

When one or more source gas (nitrogen supplying gas) selected from hydrazine and nitride oxides, which is filled in the source gas supplying part 11 of the deposition apparatus 1 of FIG. 1 is introduced into the catalyst reaction apparatus 5 from the source gas introduction port 3, a decomposition reaction of the source gas takes place due to the catalyst in the form of microparticles. Because this reaction accompanies a large amount of heat, a reactive nitriding gas at temperatures of about 700° C. through about 800° C. is produced (S132). At this time, a part of the reactive nitriding gas having sufficiently high energy is vigorously ejected toward the substrate held by the substrate holder 8 through the through-holes of the plate shape members 25 of the reactive gas separator 10. The ejected reactive nitriding gas reacts with the compound gas supplied through the compound gas introduction nozzle 6 from the compound gas supplying part 12 (S134), and thus a film composed of a nitride of the compound is deposited on the substrate 7 (S136). On the other hand, a part of the reactive nitriding gas having a relatively low energy among the reactive nitriding gas that reaches the reactive gas separator 10 from the reactive gas ejection gas nozzle 4 deviates its direction from a straight direction along which the gas proceeds straight through the through-holes of the plate shape members 25, hits the plate shape member 25, flows to the side out from the reactive gas separator 10 through the gaps between the plate shape members 25, and thus no longer contributes to the film deposition. Therefore, the film of the compound is deposited on the substrate 7 from the reactive nitriding gas having high energy and the compound gas that reacts with such a reactive nitriding gas, and thus the film having excellent properties is obtained.

In the deposition apparatus and the deposition method according to the embodiments of the present invention, it is not necessary to heat the substrate to a high temperature, namely a temperature that allows a source gas to be decomposed on the substrate, a high integrity hetero-epitaxy film can be deposited on the substrate even at a temperature of 400° C. or less, which cannot be realized in a conventional thermal CVD method. Therefore, it becomes possible to obtain semiconductor materials, various electronic materials, or the like at low costs, using a substrate that is difficult to realize in conventional art. In addition, because it is not necessary to heat the substrate to a high temperature, electric power required to heat the substrate can be saved, thereby reducing an environmental load. Moreover, because it is not necessary to use a large amount of toxic ammonia, which is used in a conventional method, a toxic gas facility is not necessary. Therefore, an environmental load is further reduced.

### Examples

Next, examples of depositing a metal oxide thin film and a metal nitride thin film employing the deposition apparatus according to the embodiment of the present invention are explained. The following specific examples do not limit the present invention. In the following, XRD patterns and ω rocking curves are obtained employing an X-ray diffraction apparatus “RAD-III” of Rigaku Corporation according to an ordinary method in order to evaluate crystalline and orientation properties of the obtained metal compound thin films.

### Example 1

In this example, a zinc oxide film is deposited on a sapphire substrate employing the deposition apparatus 1 shown in FIG. 1, namely the deposition apparatus 1 having the catalyst reaction apparatus 5 shown in FIGS. 2 and 3.

First, γ-Al₂O₃ carriers of 1.0 g having an average particle size of 0.3 mm were impregnated with platinum (IV) chloride hexahydrate of 0.27 g and sintered at 450° C. under atmosphere for four hours to obtain Pt/γ-Al₂O₃ carriers of 10 wt %. The γ-Al₂O₃ of 0.27 g having an average particle size of 0.3 mm was filled into the catalyst reaction container 22; the 10 wt % Pt/γ-Al₂O₃ catalysts of 0.02 g were filled into the catalyst reaction container 22; the metal mesh 23 was arranged; the reaction gas ejection nozzle 4 having the reactive gas separator 10 was arranged, and thus the catalyst reaction apparatus 5 was configured, which was in turn arranged inside the reaction chamber 2 evacuatable to a reduced pressure.

Next, H₂ was introduced at 0.06 atm and O₂ was introduced at 0.06 atm into the catalyst reaction apparatus 5; the H₂ and the O₂ were burnt over surfaces of the catalyst; and thus H₂O gas at a temperature of 1000° C. was produced in the catalyst reaction container 22. The high temperature H₂O gas was ejected from the reaction gas ejection nozzle 4, while the shutter 9 arranged between the reactive gas separator 10 and the substrate holder 8 was closed.

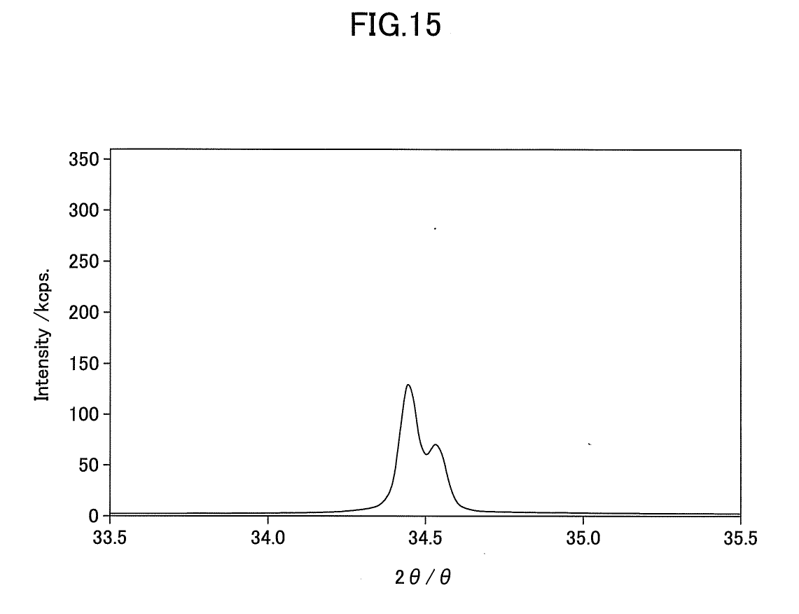

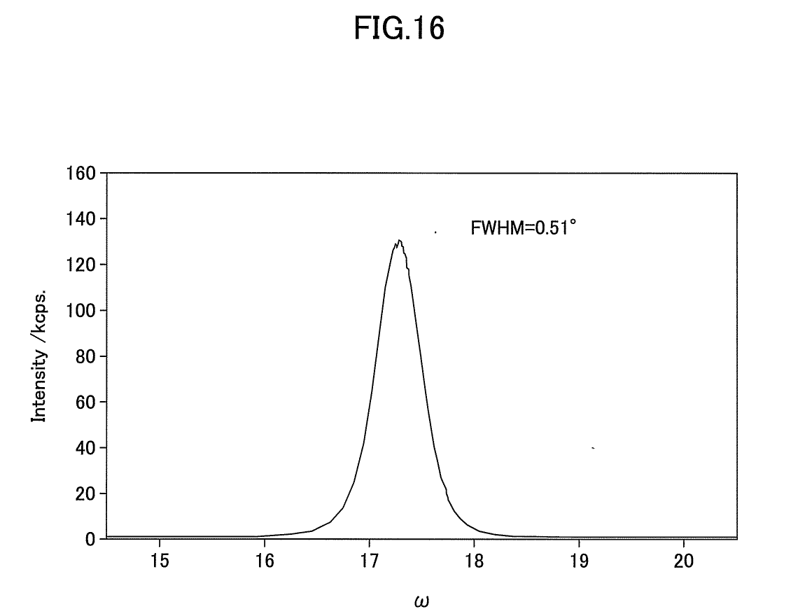

On the other hand, diethyl zinc serving as a source material of zinc oxide was supplied at a partial pressure of 1×10⁻⁶ Torr to the distal end part of the reactive gas separator 10 from the compound gas supplying part 12 via the compound gas introduction nozzle 6, and came into contact with the high temperature H₂O, thereby producing ZnO precursors. By opening the shutter 9, the ZnO precursors were supplied to a C-axis oriented sapphire substrate 7 whose surface temperature was 400° C. held by the substrate holder 8 inside the reaction chamber 2, thereby obtaining a ZnO thin film. In this example, a deposition time was 20 minutes. A film thickness of the obtained ZnO thin film was 1.0 μm. XRD patterns and co rocking curves measured for the ZnO thin film were shown in FIGS. 15 and 16, respectively.

### Example 2

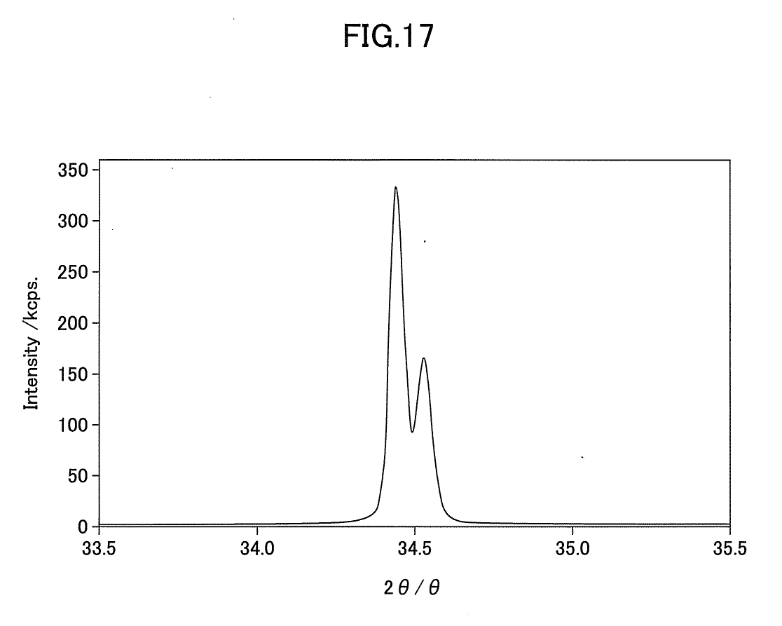

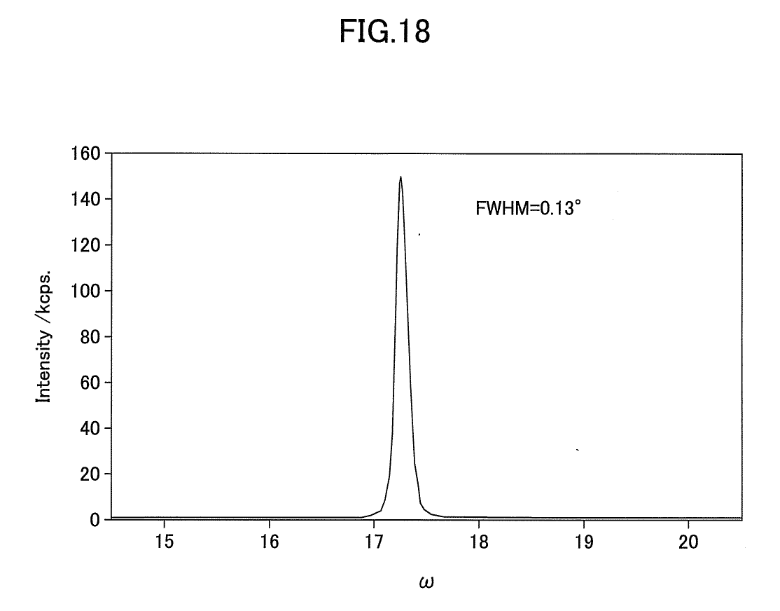

A ZnO thin film was deposited on a sapphire substrate in the same manner except that the catalyst reaction apparatus 51 shown in FIGS. 4 and 5 was used instead of the catalyst reaction apparatus 5 shown in FIGS. 2 and 3. In this example, a deposition time was 60 minutes, and a thickness of the obtained ZnO thin film as a result of the deposition was 1.3 μm. XRD patterns and ω rocking curves measured for the ZnO thin film are shown in FIGS. 17 and 18, respectively.

### Comparative Example

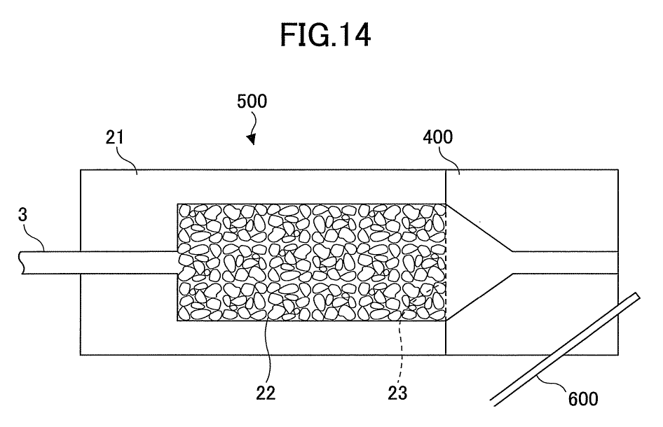

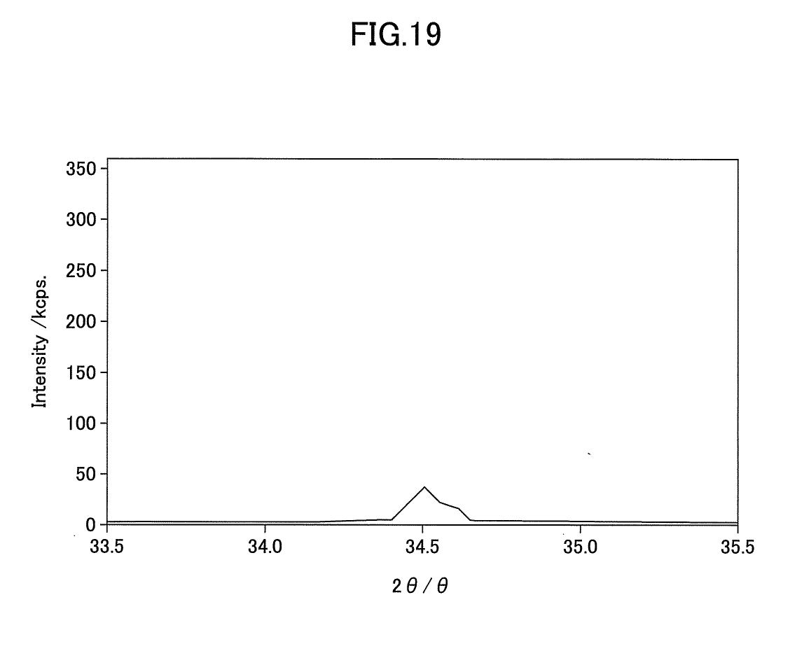

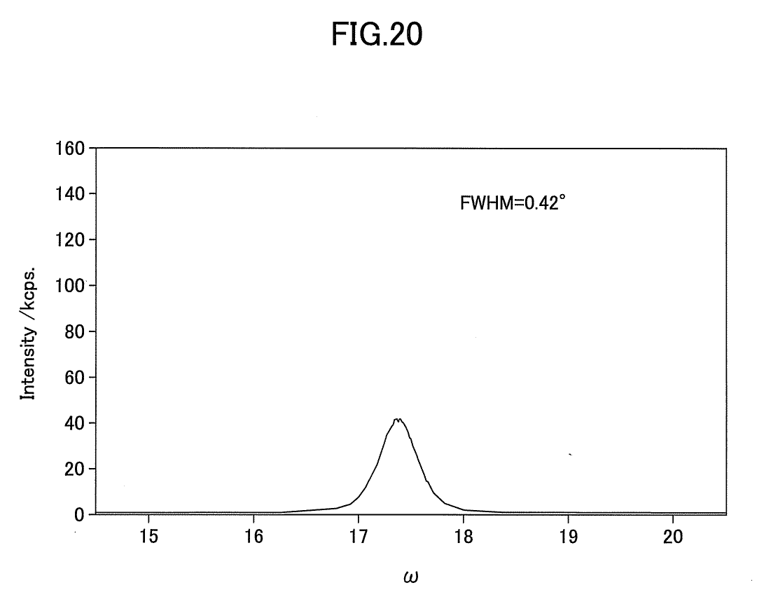

As a comparative example, a ZnO thin film was deposited on a sapphire substrate in the same manner except that a catalyst reaction apparatus 500 shown in FIG. 14 was used instead of the catalyst reaction apparatus 5 shown in FIGS. 2 and 3. No reactive gas separator is arranged in the catalyst reaction apparatus 500 as shown in FIG. 14. Specifically, in the catalyst reaction apparatus 500, the catalyst reaction container 22 configured of materials such as metal and ceramic materials is accommodated in the cylindrical reaction container 22, and the catalyst container jacket 21 is blocked by the reaction gas ejection nozzle 400. One end part of the catalyst reaction container 22 is connected to the source gas supplying part 11 via the source gas introduction port 3, and the other end part is provided with the metal mesh 23 in order to press the catalyst. In addition, a distal end part of a metal organic gas introduction nozzle 600 is fixed in a diagonal direction in relation to an ejection direction of the reactive gas to the distal end part of the reactive gas ejection nozzle 400. By using a deposition apparatus having the catalyst reaction apparatus 500 so configured, a ZnO thin film having a thickness of 1.1 μm was obtained at a deposition time of 20 minutes. XRD patterns and ω rocking curves measured for the ZnO thin film are shown in FIGS. 19 and 20, respectively.

(Evaluation of ZnO Thin Films Properties)

Regarding the ZnO thin films obtained in the corresponding examples, a volume resistivity was measured in accordance with a four probe method, and thus a carrier concentration and mobility were obtained in accordance with AC hall measurement using the measured volume resistivity.

TABLE 1

| | Hall | Carrier | |
|---|---|---|---|
| | mobility | concentration | Resistivity |
| | μ_{H} (cm²/Vs) | n (cm⁻³) | ρ (Ωcm) |
| Example 1 | 36.5 | 7.15 × 10¹⁸ | 2.28 × 10⁻² |
| Example 2 | 129 | 3.19 × 10¹⁷ | 1.52 × 10⁻¹ |
| Comp. | 10.9 | 9.70 × 10¹⁹ | 5.9 × 10⁻³ |
| Example 1 | | | |

The ZnO thin film obtained employing the catalyst reaction apparatus 500 that does not have the reactive gas separator 10 of FIG. 14 was stained brown. In addition, regarding this ZnO thin film, the carrier was 9.70×10¹⁹ cm⁻³, the carrier mobility was 10.9 cm²/Vs, and the resistivity was 5.9×10⁻³ Ωcm.

On the other hand, regarding the ZnO thin films of Examples 1 and 2 obtained by employing the catalyst reaction apparatus 5, no coloration was observed, and electric properties of the thin films were improved as shown in Table 1.

In addition, regarding the ZnO thin film of Example 2 obtained by employing the catalyst reaction apparatus 51 shown in FIGS. 4 and 5, two peaks (Kα1, Kα2) were clearly separated and the peak intensity is strong as shown in FIG. 17, compared with the XRD pattern of the ZnO thin film of Example 1 (FIG. 15). As a result, it has been found that the ZnO thin film having excellent crystalline properties was obtained. In addition, regarding the ZnO thin film of Example 2, a w rocking curve having a narrow peak width and strong peak intensity was measured as shown in FIG. 18, compared with the w rocking curve regarding the ZnO thin film of Example 1 (FIG. 16). As a result, it has been found that the thin film having a strong orientation was obtained.

When the deposition apparatus shown in FIG. 1 was configured by employing the catalyst reaction apparatus 500 shown in FIG. 14 instead of the catalyst reaction apparatus 5, and the reactive gas was ejected directly from the reaction gas ejection nozzle 400, thereby depositing a metal compound thin film, the obtained thin film stained and had electric properties inappropriate as a semiconductor material, because the reactive gas was not in the form of a beam, but was diverged to reach the substrate 7. In addition, the compound gas introduction nozzle 6 that introduces a source material for depositing the thin film was clogged by the reactive gas, and thus the film deposition cannot be continuously carried out for 20 minutes or more.

On the other hand, when the deposition apparatus 1 of FIG. 1 having the catalyst reaction apparatus 5 shown in FIGS. 2 and 3 is employed to deposit the thin film on the substrate 7, the reactive gas is ejected in the form of a beam and proceeds more straight, because excessive reactive gas is evacuated through the gaps between the pillars 26 of the reactive gas separator 10 and the plural plate shape members 25 having the through-holes at the center are arranged to intersect with the ejection direction of the reactive gas. As a result, coloration of the obtained thin film can be reduced, and additionally, electric properties are improved.

While the present invention has been explained with reference to the above embodiments, the present invention is not limited to the disclosed embodiment, but may be altered or modified with the scope of the accompanying claims. For example, the reactive gas separator 101 may be arranged at the distal end part of the reaction gas ejection nozzle 4 of the catalyst reaction container 41, and the reactive gas separator 10 may be arranged at the distal end part of the reaction gas ejection nozzle 41. In addition, the catalyst may be filled in a part of the catalyst reaction container 22 or the like, rather than entirely.

This international application claims priority based on a Japanese Patent Application No. 2008-017413 filed on Jan. 29, 2008, the entire content of which is hereby incorporated by reference.

1. A deposition apparatus comprising:
a catalyst reaction apparatus including
an introduction part that introduces a first source gas,
a catalyst container that contains a catalyst that produces reactive gas from the first source gas introduced from the introduction part, and
a reactive gas ejection part that ejects the reactive gas from the catalyst container;
a reactive gas separator that allows the reactive gas ejected from the reactive gas ejection part to go therethrough;
a substrate supporting part that supports a substrate; and
a supplying part that supplies a second source gas that reacts with the reactive gas that passes through the reactive gas separator, so that a film is deposited on the substrate.

2. The deposition apparatus recited in claim 1, wherein the catalyst reaction apparatus is arranged inside a reaction chamber evacuatable to a reduced pressure,
wherein the second source gas is a metal organic compound gas, and
wherein the reactive gas separator has a gap in a side surface.

3. The deposition apparatus recited in claim 1, wherein the reactive gas separator includes plural plate shape members each of which has a through-hole,
wherein at least two adjacent plate shape members among the plural plate shape members are arranged so that a gap is formed between the two adjacent plate shape members.

4. The deposition apparatus recited in claim 1, wherein the reactive gas separator includes a cap in the form of a funnel, the cap being arranged to provide a gap in relation to the reactive gas ejection part,
wherein the cap includes an opening in an apex thereof and has a diameter that becomes larger along an ejection direction of the reactive gas ejected from the reactive gas ejection part.

5. The deposition apparatus recited in claim 1, wherein a distal end part of the supplying part that supplies the second source gas is arranged adjacent to the reactive gas separator.

6. The deposition apparatus recited in claim 1, further comprising a shutter that is openable/closable, and arranged between the reactive gas separator and the substrate supporting part.

7. The deposition apparatus recited in claim 1, wherein the introduction part is connected to a source gas supplying part that contains a source gas selected from a mixed gas of H₂ gas and O₂ gas, H₂O₂ gas, hydrazine, and nitride.

8. The deposition apparatus recited in claim 1, wherein the catalyst container is blocked by the reactive gas ejection part.

9. The deposition apparatus recited in claim 1, wherein the catalyst container is divided into plural compartments by separators each of which has a communication hole, and wherein the catalyst is arranged in each of the plural compartments.

10. The deposition apparatus recited in claim 1, wherein the catalyst includes a carrier having an average particle size ranging from 0.05 mm through 2.0 mm, and a catalyst component having an average particle size ranging from 1 nm through 10 nm, the catalyst component being carried by the carrier.

11. The deposition apparatus recited in claim 10, wherein the carrier may be formed by subjecting porous γ-alumina to a thermal process at 500 through 1200° C. to transform the porous γ-alumina crystal phase into an α-alumina crystal phase while maintaining the surface structure thereof.

12. A deposition apparatus comprising:
a catalyst reaction apparatus including
an introduction part that introduces a first source gas;
a catalyst container that contains a catalyst that produces a reactive gas from the first source gas introduced from the introduction part; and
a reactive gas ejection part that ejects the reactive gas from the catalyst container, the reactive gas ejection part including
a diameter reducing part whose inner diameter becomes smaller along an ejection direction of the reactive gas, and
a diameter enlarging part whose inner diameter becomes larger along the ejection direction;
a substrate support part that supports a substrate; and
a supplying part that supplies a second source gas that reacts with the reactive gas ejected from the reactive gas ejection part, so that a film is deposited on the substrate.

13. The deposition apparatus recited in claim 12, wherein the catalyst reaction apparatus is arranged in a reaction chamber evacuatable to a reduced pressure, and wherein the second source gas is a metal organic compound gas.

14. The deposition apparatus recited in claim 12, further comprising a reactive gas separator including a cap in the form of a funnel, the cap being arranged providing a gap in relation to the reactive gas ejection part, wherein the cap includes an opening in an apex thereof and has a diameter that becomes larger along an ejection direction of the reactive gas ejected from the reactive gas ejection part.

15. The deposition apparatus recited in claim 12, wherein a distal end part of the supplying part that supplies the second source gas is arranged in order to meet the diameter enlarging part.

16. The deposition apparatus recited in claim 14, wherein a distal end part of the supplying part that supplies the second source gas is arranged adjacent to the reactive gas separator.

17. The deposition apparatus recited in claim 12, further comprising a shutter that is openable/closable and arranged between the reactive gas separator and the substrate supporting part.

18. The deposition apparatus recited in claim 12, wherein the introduction part is connected to a source gas supplying part that contains a source gas selected from a mixed gas of H₂ gas and O₂ gas, H₂O₂ gas, hydrazine, and nitride.

19. The deposition apparatus recited in claim 12, wherein the catalyst container is blocked by the reactive gas ejection part.

20. The deposition apparatus recited in claim 12, wherein the catalyst container is divided into plural compartments by separators each of which has a communication hole, and wherein the catalyst is arranged in each of the plural compartments.

21. The deposition apparatus recited in claim 12, wherein the catalyst includes a carrier having an average particle size ranging from 0.05 mm through 2.0 mm, and a catalyst component having an average particle size ranging from 1 nm through 10 nm, the catalyst component being carried by the carrier.

22. The deposition apparatus recited in claim 21, wherein the carrier may be formed by subjecting porous γ-alumina to a thermal process at 500 through 1200° C. to transform the porous γ-alumina crystal phase into an α-alumina crystal phase while maintaining the surface structure thereof.

23. A deposition method comprising steps of:
producing a reactive gas by introducing a first source gas into a catalyst container that contains a catalyst that produces the reactive gas from the first source gas;
introducing the reactive gas produced in the catalyst container to a reactive gas separator that allows the reactive gas to flow therethrough and has a gap in a side surface thereof, and supplying a second source gas so that the reactive gas that passes through the reactive gas separator reacts with the second source gas; and
depositing a film on a substrate by exposing the substrate to a precursor produced through reaction of the reactive gas and the second source gas.

24. A deposition method comprising steps of:
producing a reactive gas by introducing a first source gas into a catalyst container that contains a catalyst that produces the reactive gas from the first source gas;
introducing the reactive gas produced in the catalyst container to a reactive gas ejection part that includes a diameter reducing part whose inner diameter becomes smaller along an ejection direction of the reactive gas, and a diameter enlarging part whose inner diameter becomes larger along the ejection direction, and supplying a second source gas so that the reactive gas ejected from the reactive gas ejection part reacts with the second source gas; and
depositing a film on a substrate by exposing the substrate to a precursor produced through reaction of the reactive gas and the second source gas.

25. A deposition method comprising steps of:
producing a reactive gas by introducing a first source gas into a catalyst container that contains a catalyst that produces the reactive gas from the first source gas;
introducing the reactive gas produced in the catalyst container to a reactive gas ejection part that includes a diameter reducing part whose inner diameter becomes smaller along an ejection direction of the reactive gas, and a diameter enlarging part whose inner diameter becomes larger along the ejection direction;
introducing the reactive gas ejected from the reactive gas ejection part to a reactive gas separator including a cap in the form of a funnel, the cap including an opening in an apex thereof and having a diameter that becomes larger along an ejection direction of the reactive gas ejected from the reactive gas ejection part, and introducing a second source gas so that the reactive gas that passes through the reactive gas separator reacts with the second source gas; and
depositing a film on a substrate by exposing the substrate to a precursor produced through reaction of the reactive gas and the second source gas.
